(19) United States
(12) Patent Application Publication
(10) Pub. No.: US 2022/0404528 A1
(43) Pub. Date: Dec. 22, 2022

(54) Wide bandgap oxide nanostructure anti-glare coating and use thereof

(71) Applicants: David ROGERS, Sainte Savine (FR); Philippe Henri BOVE, Gif sur yvette (FR); Ferechteh HOSSEINI TEHERANI, Orsay (FR); Vinod Eric SANDANA, Garges-Lès-Gonesse (FR)

(72) Inventors: David ROGERS, Sainte Savine (FR); Philippe Henri BOVE, Gif sur yvette (FR); Ferechteh HOSSEINI TEHERANI, Orsay (FR); Vinod Eric SANDANA, Garges-Lès-Gonesse (FR)

(21) Appl. No.: 17/840,743

(22) Filed: Jun. 15, 2022

(30) Foreign Application Priority Data
Jun. 15, 2021 (FR) FR2106340

(51) Int. Cl. G02B 1/118; G02B 1/14; G02F 1/1335

(52) U.S. Cl. CPC G02B 1/118; G02B 1/14; G02F 1/133502

(57) ABSTRACT

The invention provides an anti-glare coating of wide bandgap nanostructured oxide material so as to reduce the dazzling reflections of sunlight and avoid light pollution generated by spacecraft. The coating provides selective electrodeposition of a nanostructured wide bandgap oxide material on the metal contact grid on the surface of a solar panel of a spacecraft or a satellite in which the metal contact grid constitutes the cathode, and the resulting nanostructures have a width and spacing less than the wavelength ‘λ’ of the incident light or equal to ‘λ/n’ with λ located between 180 nm and 8μm, and ‘n’ being the refractive index of the nanostructured material so that for angles of incidence between 0.01 and 90 degrees less than 0.5% of light is reflected.

### FIELD OF THE INVENTION

The subject of this invention is a nanostructured anti-glare coating of a wide bandgap oxide for solar panels. In particular, the invention concerns an anti-glare coating of prohibited wide-band nanostructured oxide materials on the metal contact grid on the surface of the solar panels of spacecraft.

The field of use of this invention is on spacecraft and satellites and, in particular, in nanosatellites.

### BACKGROUND

Anti-reflective coatings (ARC) made up of single or multilayered dielectric layers form the basis of conventional design for the suppression of reflections from cover-glasses on space solar panels. Nanostructuration allows greater flexibility in the design and manufacture of coatings, which have significantly advanced the field of ARCs. Furthermore, the emergence of plasmonic and metal material surfaces have allowed the realization of broadband ARC coatings that are both insensitive angle of incidence and an order of magnitude thinner.

A conventional thin film type anti-reflective coating can minimize reflections for a specific wavelength, and usually at normal angle of incidence, which prohibits its use for broadband light. In addition, such coatings are inherently incapable of producing a reduction of reflection over a wide range of incidence angles.

Conventional single, double or multilayer anti-reflective coatings are also limited by thickness constraints. These fundamental limitations hinder further improvement in their performance, in particular with respect to the current demand for low-thickness and broadband applications in many optoelectronic devices. Nanofabrication and nanophotonics have matured the field of ARCs. These new conceptions and approaches could improve the performance of many devices for which light reflection is undesirable, such as solar cells and photodetectors. However, long-term stability, mechanical robustness and the cost/complexity of making plasmon and metal material surface-based ARCs remain obstacles.

Anti-reflective coatings (ARC) consisting of two layers of dielectrics are commonly used to suppress reflection from the “cover-glass” of space solar panels.

However, the metal contact grid on the surface of the solar panels located below cover glass, on space vessels, strongly reflects, sunlight towards the Earth. This glare problem is increased with nanosatellites (or cubesats) because they are very numerous and do not have a propulsion/pointing system, so they constantly rotate and thus reflect sunlight intermittently. This phenomenon is a major cause of light pollution in space.

The invention aims at a coating to solve the problem of light reflection from the metallic contacts of solar panels on space vessels/satellites.

In particular, the invention consisting of a low-cost nanostructured coating of wide bandgap oxide which efficiently reduces the dazzling reflections of light.

### SUMMARY OF THE INVENTION

To this end, the invention proposes an anti-glare coating of wide-bandgap nanostructured oxide material to reduce the dazzling reflections of sunlight and avoid light pollution generated by spacecraft. The wide-bandgap oxide nanostructure coating can be carried out selectively on the metal contact grid on the surface of a solar panel of a spacecraft by electrodeposition with the metal contact grid constituting the cathode in that deposit. The resulting nanostructures should have a width and spacing less than the wavelength ‘λ’ of the incident light or equal to ‘λ/n’ with λ between 180 nm and 8 μm, and ‘n’ is the refractive index of the nanostructured material so that for angles of incidence between 0.01 and 90 degrees less than 0.5% of light is reflected.

In the electrodeposition, the metal contact grid (constituting the negative electrode or cathode) and a positive electrode (or anode) are immersed directly in an electrolyte solution which is saturated with oxygen, and a constant voltage is applied between the anode and the cathode. A nanostructured oxide material is deposited on the metal contact grid when the deposition is carried out at a temperature of around 70° C.

According to particular characteristics, the obtained nanostructures of oxide have morphologies such as ‘nanowires’ or ‘nanocones’.

In various embodiments, the wide-bandgap nanostructured oxide can bec ZnxOy or ZnₓMg_{y}O_{z} or ZnₓMg_{y}N_{z} O_{w}orGaₓ O_{z}orGaₓSi_{y}O_{z}or GaₓO_{z} or TiₓO_{z} or MgₓO_{z} or AlxO_{z} or SnₓO_{z} with indices x, y, z and w between 1 and 3.

In one realization the wide bandgap nanostructured oxide material is zinc oxide (ZnO).

The invention also concerns the use of a solar panel in a nanosatellite or spacecraft, including on its surface a grid of metal contacts covered with anti-glare coating of a nanostructured wide bandgap oxide, so as to reduce the dazzling reflections/glare of sunlight and to avoid light pollution generated by spacecraft.

The invention also concerns a nanosatellite whose metal contact grid on the surface of its solar panels is covered by an anti-glare coating of nanostructured oxide materials as defined above.

### BRIEF DESCRIPTION OF THE FIGURES

FIG. 1 illustrates a bright reflection from the metal contact grid on the surface of a nanosatellite solar panel,

FIG. 2 illustrates the electrodeposition technique for deposition of a layer of ZnO nanowires or nanocones selectively on a metal contact grid,

FIG. 3 represents different morphologies of oxide nanostructure of the present invention capable of forming an anti-glare coating on a metal contact grid,

FIG. 4 illustrates the effect of light on a wide bandgap oxide nanocones FIG. 4A and FIG. 4B,

FIG. 5 illustrates the image of the light reflection glare from satellites, as seen from the earth.

### DETAILED DESCRIPTION

Nanostructured wide bandgap oxides are among the most important nanomaterials due to their distinctive properties along with the relative ease of low-cost manufacture of a multitude of structures. Moreover, wide bandgap oxides are often physically and chemically stable. The wide range of their properties make them the materials of choice in many applications such as photovoltaic cells, photodetectors, transparent electrodes, energy generators or harvestors, gas sensors, photocatalytic reactors for air and water pollution control, etc.

There are a wide variety of forms of oxide nanostructures. They can be of natural origin, but can also be produced artificially through different physical and/or chemical processes, using appropriate growth processes and controlling growth kinetics, local growth temperature and the chemical composition of precursors.

FIG. 1 illustrates the image of light reflection from the metal surfaces of a nanosatellite. Indeed, metal contacts of solar panels reflect sunlight and are currently a main cause of light pollution in space when satellites are in orbit.

To reduce the reflection of sunlight, an anti-glare coating is made directly on these metal contact grids (as it is those metal contact grids that strongly reflect sunlight). For the realization of this selective coating, the metal contact grid is used as the positive electrode in an electrodeposition.

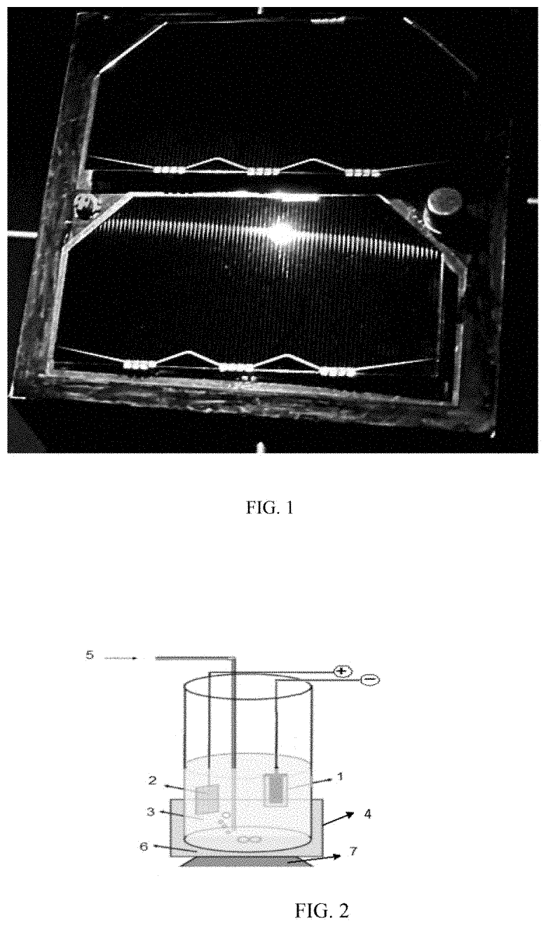

FIG. 2 illustrates the electrodeposition technique for a layer of ZnO nanowires on the electrical contact grid on the surface of a solar panel of a nanosatellite. The contact grid (1) acts as a negative electrode (cathode) while zinc(2) acts as a positive electrode (anode). The electrolyte (3) consists of Potassium Chloride (KCl) and dimethyl hexamethylenetetramine. The electrolyte (3) is saturated with oxygen using a bubbler (5) of gaseous molecular oxygen. The ensemble is placed in a recipient (4) containing a liquid (6) such as water. The liquid is heated by means of a hot plate (7). The electrodeposition of zinc oxide on the contact grid is made at slightly elevated temperature.

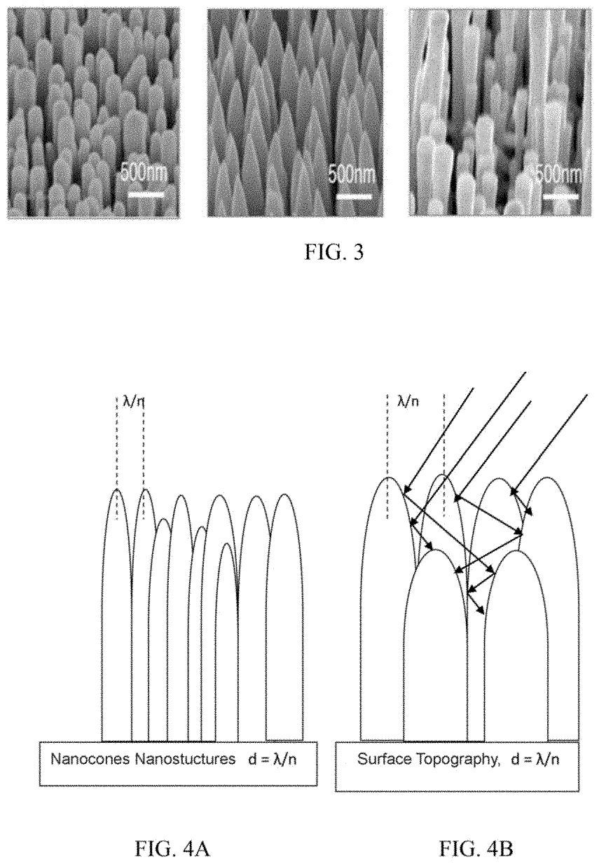

FIG. 3 illustrates such an anti-glare coating consisting of self-formed networks of ZnO aligned nanostructures with various morphologies such as nanowire or nanocone networks. Among these, the conical or nanocone form has shown remarkable anti-glare performance. The light reflection for these conical shapes is less than 0.5% for the entire spectrum visible from angles of incidence as low as 0.01° (degree).

The anti-glare effectiveness of the oxide nanostructures made according to this invention is strongly related to the morphology of nanocones and their size relative to the incident light wavelengths (FIG. 4A). Indeed, the width and spacing of nanocones should be approximately equal to “λ/n” where λ is the wavelength of the incident light and n is the refractive index of the nanostructured oxide material. Under these conditions we noticed that the reflection of light is less than or equal to 0.5% even for grazing incidence angles down to 0.01° (FIG. 4B). This shows the anti-glare effectiveness of the metal contact grid nanostructured coating claimed in this invention.

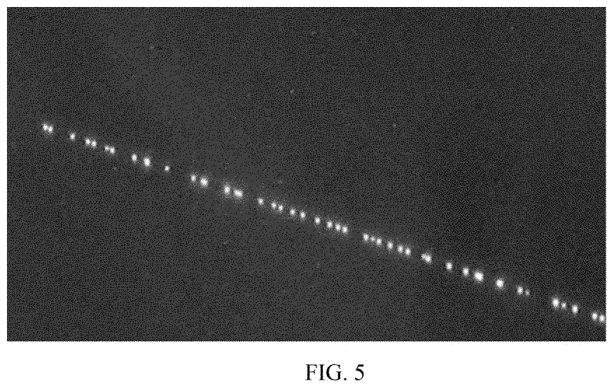

FIG. 5 shows an image, obtained from Earth, of satellites positioned in low orbit. In this image, we notice a train of spacecraft with reflections as brilliant as the light from the Pole star. Indeed, the specific problem of small cubesats/nanosatellites is related to the lack of a pointing/propulsion system to direct the solar panels at the sun. Thus, they constantly rotate on themselves and their metallic surfaces reflect sunlight, intermittently, to Earth.

Broadband anti-glare coatings of wide bandgap oxide nanostructures can provide a solution to the problem of light reflection, even at such varying and broad incidence angles.

### Description of a Method of Realisation of the Invention

In the method of production presented in FIG. 2 a nanostructured film of ZnO is deposited on the metal contact grid on the surface of a nanosatellite solar panel by electrodeposition, in an electrolyte solution consisting of potassium chloride (KCl) and methyl hexamethylene tetramine. Using the metal contact grid as a negative electrode (cathode) and zinc (Zn) as a positive electrode (anode). The deposition is carried out at a temperature of about 70° C. The length of nanowires or nanocones can be increased by increasing the concentration of KCl. A bubbler (Oxygen) is used to saturate the electrolyte in oxygen and thus promote Zn oxidation. Nanostructured zinc oxide is thus deposited on the metal contact grid at a relatively low temperature of about 70° C. This technique of nanostructure growth by selectively electroplating a metal contact grid is particularly well suited to obtain high-quality nanostructured layers at manufacturing temperatures sufficiently low to be compatible with temperature-sensitive supports such as the solar cells used on satellites.

In addition, light is scattered more from rougher surfaces, such as that constituted by ZnO nanowire or nanocones. This reduces reflection.

The nanostructured anti-glare coating on a metal contact grid of a solar panel, according to the present invention, is used in spacecraft or nanosatellites to reduce the reflection of light towards the earth. Indeed, when these nanosatellites are in orbit, they constantly rotate on themselves and reflect light on Earth. When equipped with solar panels with anti-glare coating on their metal contact grids, the reflection is diminished, even for grazing incidence angles.

The invention concerns, in particular, nanosatellites where a metal contact grid on the surface of its solar panels is covered by anti-glare coating of nanostructured oxide materials, according to the present invention.

The advantages of the anti-glare coating of wide bandgap oxide nanostructures realized by electro deposition according to the present invention are that it is high effective for glare reduction and that it is obtained with a minimum cost and at a relatively low temperature.

The electrodeposition technique with the metal contact grid acting as a positive electrode, on which a wide bandgap nanostructured oxide material is selectively deposited on the metal, is well suited to solve the anti-glare problem of nanosatellites, when in low orbit.

1. An anti-glare coating of wide bandgap nanostructured oxide material which reduces the dazzling reflections of sunlight and avoids light pollution generated by spacecraft which is realized by the electrodeposition of a nanostructured wide-bandgap oxide material on the metal contact grid on the surface of a solar panel of a spacecraft or satellite in which the metal contact grid forms the cathode, and the resulting nanostructures have a width and a spacing less than the wavelength ‘λ’ of the incident light or equal to ‘λ/n’ with λ between 180 nm and 8 μm, and ‘n’ being the refractive index of the nanostructured material so that for angles of incidence between 0.01 and 90 degrees less than 0.5% of light is reflected.

2. The anti-glare coating of nanostructured material obtained by electrodeposition according to claim 1 in which the metal contact grid constituting the negative electrode (or cathode) is immersed in an electrolyte solution, which is saturated with oxygen, with a positive electrode (anode), having a constant voltage between the anode and the metal contact grid, such that there is deposition of a nanostructured oxide on the metal contact grid, at a temperature of around 70° C.

3. The anti-glare coating of nanostructured oxide material according to claim 1 wherein the nanostructures obtained have morphologies such as ‘nanowires’ or ‘nanocones’.

4. The anti-glare coating of oxide nanostructures according to claim 1 wherein the oxide materials are chosen from ZnₓO_{y} or ZnₓMg_{y}O_{z} or ZnₓMg_{y}N_{z}o_{w}or GaₓSi_{y}O_{z}or TiO_{z} or MgₓO_{z} or AlₓO_{z} or SnₓO_{z} with indices x, y, z and w between 1 and 3.

5. The anti-glare coating of oxide nanostructure material according to claim 1, wherein the oxide material is zinc oxide.

6. Use of a solar panel on a nanosatellite or spacecraft, having a metal contact grid covered with an anti-glare coating of nanostructured wide band gap oxide according to claim 1, so as to reduce the dazzling reflections of sunlight and to avoid light pollution generated by spacecraft.

7. A nanosatellite whose metal contact grid on the surface of its solar panels is covered by anti-glare coating of nanostructured oxide material, according to claim 1.
